(19) United States
(12) Patent Application Publication
(10) Pub. No.: US 2011/0267048 A1
(43) Pub. Date: Nov. 3, 2011

(54) MAGNETICALLY SENSITIVE DEVICES

(76) Inventors: Alexandre Bratkovski, Mountain View, CA (US); Iakov Kopelevitch, Mountain View, CA (US)

(21) Appl. No.: 12/770,502

(22) Filed: Apr. 29, 2010

(51) Int. Cl. G01R 33/02

(52) U.S. Cl. 324/244

(57) ABSTRACT

Methods and apparatus pertaining to magnetically sensitive devices are provided. A device includes a graphite containing-material (GCM) supported in contact with respective pairs of electrodes. The GCM is subject to a magnetic field. Various levels of electric current are driven through the GCM, while corresponding voltage measurements are taken. Resulting current-versus-voltage data pairs are compared to calibration data for the device. Magnetic field intensities, operating states of the device or other determinations can be made according to the comparison.

### BACKGROUND

Electronic circuitry uses various types of devices and components, characterized by respective functions, to perform a myriad of operations. Data storage, sensing and measuring instrumentation, computation, and power regulation are just a few of an unlimited number of applications handled by electronic apparatus.

Electronic circuits evolve in terms of reliability, breadth of application and other dimensions as new types of electronic components are developed. One area of interest lies in devices whose electrical behavior is influenced by incident magnetic fields. The present teachings are directed to magnetically sensitive devices.

### BRIEF DESCRIPTION OF THE DRAWINGS

The present embodiments will now be described, by way of example, with reference to the accompanying drawings, in which:

FIG. 1 is an isometric diagram of a device according to one embodiment;

FIG. 2 is a signal diagram depicting illustrative electrical response curves according to the embodiment of FIG. 1;

FIG. 3 is an isometric block diagram of a system according to yet another embodiment;

FIG. 4 is block schematic diagram depicting an apparatus according to one embodiment;

FIG. 5 is a flow diagram depicting a method according to one embodiment;

FIG. 6 is a flow diagram depicting a method according to another embodiment.

### DETAILED DESCRIPTION

### Introduction

Devices and methods are provided in regard to magnetically sensitive devices and apparatus. A device includes a graphite containing-material (GCM) supported in contact with respective pairs of electrodes. The GCM is subject to a magnetic field. Various levels of electric current are driven through the GCM by way of one electrode pair, while corresponding voltage measurements are taken by way of the other electrode pair. Resulting current-versus-voltage data pairs are compared to predetermined calibration data for the device. Magnetic field intensities, operating states of the device, or other determinations can be made in accordance with the comparison.

In one embodiment, an apparatus includes a substrate and a graphite containing-material supported by the substrate. The apparatus also includes a first pair of electrodes configured to subject the graphite containing-material to an electric current. The apparatus further includes a second pair of electrodes configured to sense an electric potential while the graphite containing material is subject to the electric current.

In another embodiment, a method includes the step of subjecting a device, including a graphite containing-material, to a magnetic field. The method also includes sensing an electric potential across the graphite containing-material. The method further includes determining at least a state of the device or an intensity of the magnetic field by way of the electric potential.

### First Illustrative Device

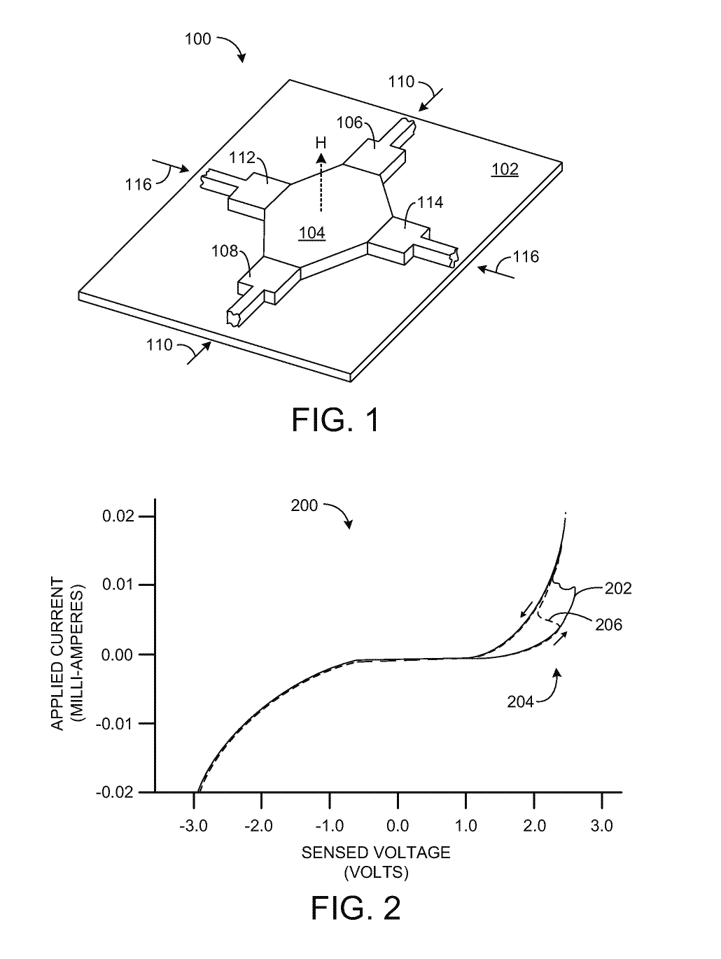

Reference is now directed to FIG. 1, which depicts an isometric diagram of a device 100. The device 100 is illustrative and non-limiting with respect to the present teachings. Thus, other devices, apparatus or systems can be configured and/or operated in accordance with the present teachings.

The device 100 includes a substrate 102. The substrate 102 can be any suitable supporting material. In one embodiment, the substrate 102 is defined by a silicon wafer. In another embodiment, the substrate 102 is another semiconductor material. Other substrates can also be used.

The device 100 also includes a graphite containing-material (GCM) 104 supported by the substrate 102. The GCM 104 can be defined by various graphite and graphite-based materials. In one embodiment, the GCM 104 is defined by a plurality of layers of graphene. Other materials can also be used. In one embodiment, the GCM 104 is defined by a width in the range of fifty to two-hundred nanometers (nm), a length in the range of fifty to two-hundred nm, and a thickness in the range of eighty to two-hundred nm. Other suitable dimensions can also be used. The GCM 104 is depicted as having a particular, “truncated diamond” shape. However, it is to be understood that other shapes and form-factors can also be used.

The device 100 also includes respective electrodes 106 and 108. Each of the electrodes 106 and 108 can be formed from any suitable, electrically-conductive (or semi-conductive) material. Non-limiting examples of such materials include silver, gold, platinum, copper, etc. Other materials can also be used. The electrodes 106 and 108 are disposed on generally opposite sides of the GCM 104, thus defining a first electrode axis 110.

The electrodes 106 and 108 are configured to subject the GCM 104 to an electrical current provided by an external source entity (not shown). In one embodiment, the electrode 106 is coupled to a negative electrical potential, while the electrode 108 is coupled a positive electrical potential. Current can also be driven in the opposite polarity. The electrodes 106 and 108 respectively define a first pair of electrodes.

The device 100 further includes respective electrodes 112 and 114. Each of the electrodes 112 and 114 can be formed from any suitable, electrically-conductive (or semi-conductive) material. Non-limiting examples of such materials include silver, gold, platinum, copper, etc. Other materials can also be used. The electrodes 112 and 114 are disposed on generally opposite sides of the GCM 104, thus defining a second electrode axis 116. It is noted that the first electrode axis 110 is perpendicular (or nearly so) to the second electrode axis 116. The electrodes 112 and 114 respectively define a second pair of electrodes.

The electrodes 112 and 114 are configured to sense an electric potential exhibited across the graphite containing-material 104 when an electric current is driven there through by way of electrodes 106 and 108. In one embodiment, the electrode 112 senses a positive electrical potential, while the electrode 114 sense a negative electrical potential. Current can also be sensed in the opposite polarity.

The device 100 is configured to be sensitive to magnetic lines of flux “H” incident to the graphite containing-material 104. The magnetic field response of the device 100 is characterized by respective current-versus-voltage response curves. Each current-versus-voltage response curve corresponds to particular incident magnetic field intensity. Thus, the device 100 is characterized by distinct electrical states that differ in accordance with the intensity of the applied magnetic field “H”. This magnetically sensitive behavior will be further described hereinafter.

Attention is now directed to FIG. 2, which is a signal diagram 200 depicting respective electrical response curves for device 100. The signal diagram 200 is illustrative and non-limiting in nature. Thus, other magnetically sensitive devices can be configured and/or operated in accordance with the present teachings that correspond to respectively varying electrical response curves.

A first electrical response curve (curve) 202 is depicted. The curve 202 (i.e., solid line) depicts the applied current versus sensed voltage (i.e., current-versus-voltage) response of the device 100 when subject to zero (ambient, or background) magnetic field intensity in direction “H”. Thus, the curve 202 corresponds to the device 100 response to a zero Oersted field. The curve 202 depicts the varying electrical potential sensed across the GCM 104 by way of electrodes 112 and 114 in response to varying values of electrical current driven through the GCM 104 by way of electrodes 106 and 108.

It is noted that the curve 202 exhibits hysteresis in a region 204 of the signal diagram 200. Specifically, electric potential sensed at electrodes 112 and 114 increases with increasing applied current, up to a “fold back” locus at about two-point-six volts correspondent to zero-point-zero-one milli-amperes of applied current.

In turn, a second electrical response curve 206 is depicted. The curve 206 (i.e., dashed line) depicts current-versus-voltage response of the device 100 when subject to a magnetic field intensity “H” of about five-hundred Oersteds. It is noted that the curve 206 also exhibits hysteresis in the region 204. However, the electric potential sensed at electrodes 112 and 114 increases up to a different fold back locus at about two-point-four volts correspondent to zero-point-zero-zero-five milli-amperes of applied current. It is noted that the curves 202 and 206 closely correspond except in the region 204.

The current-versus-voltage curves (e.g., 202 and 206) exhibited by the device 100 differ sufficiently to allow a particular, incident magnetic field intensity “H” to be determined (or nearly so). The different curves 202 and 206 are also considered to represent different states for the device 100. It is to be understood that any number of current-versus-voltage response curves can be determined for the device 100 corresponding to respective magnetic field intensities. Such a collection of curves—or particular current/voltage loci selected there from—can be used to compile calibration data for the device 100 or any other magnetically sensitive device according to the present teachings.

### First Illustrative System

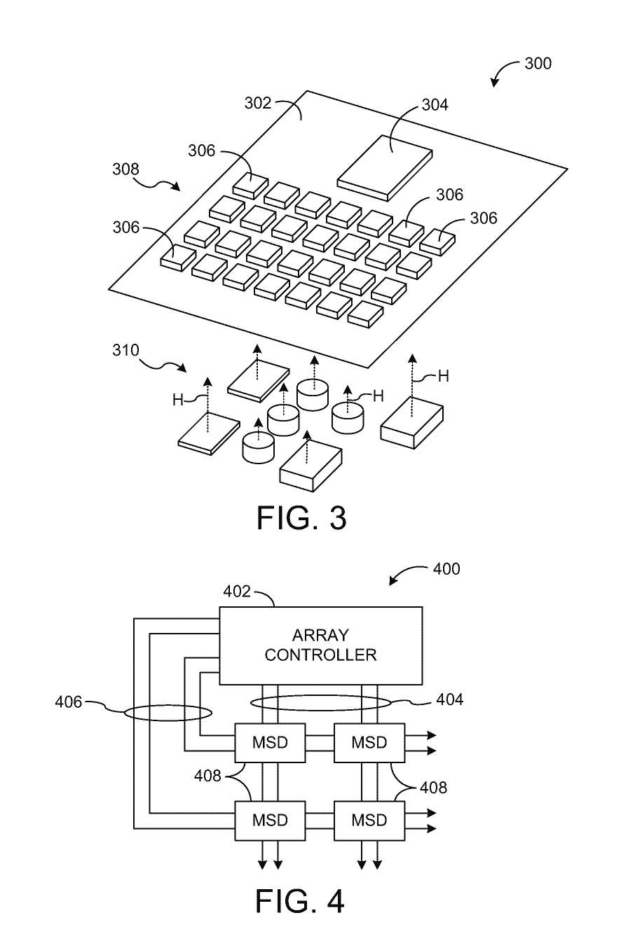

Attention is now directed to FIG. 3, which depicts an isometric block diagram of a system 300 according to another embodiment. The system 300 is illustrative and non-limiting with respect to the present teachings. Thus, other systems or apparatus can be configured and/or operated in accordance with the present teachings.

The system 300 includes a supporting substrate 302. The substrate 302 can be a circuit board or card, a semiconductor wafer, etc. Other suitable substrates can also be used. The system 300 also includes an array controller 304 supported by or formed upon the substrate 302. The controller 304 is configured to individually address and access a plurality of magnetically sensitive devices 306 described hereinafter. The controller 304 can be variously defined and configured in accordance with operations to be performed thereby. For purposes of non-limiting example, it is assumed that the controller 304 is defined by an application specific integrated circuit (ASIC). In another embodiment, the controller 304 is defined, at least in part, by a microprocessor or microcontroller. Other suitable embodiments can also be used.

The system 300 further includes a plurality of magnetically sensitive devices (MSDs) 306 as introduced above. The MSDs 306 are distributed (or formed) on and supported by the substrate 302 such that an array 308 is defined. Each MSD 306 is configured to exhibit distinct current-versus-voltage response curves in accordance with incident magnetic flux density. In one embodiment, each MSD 306 is substantially equivalent to the device 100 as described above. Other suitable configurations according to the present teachings can also be used. The controller 304 is configured to provide controlled drive current to, and sense the corresponding voltages exhibited by, the MSDs 306.

The controller 304 is further configured to determine respective electrical states for each MSD 306 based on the sensed voltages. Additionally (or alternatively), the controller 304 is configured to determine respective magnetic field intensities incident to each of the MSDs 306. In this way, the array 308 of MSDs 306 can be operated as a magnetic field sensing apparatus.

The system 300 further includes a plurality of various entities 310. Each of the entities 310 can be variously defined and configured. The specific definition and function of each entity 310 is not germane to the present teachings, and such are provided in the interest of illustration. However, each entity 310 is characterized by a respective magnetic field “H” during at least some normal operating states. Such magnetic fields “H” can be constant or varying, respectively, on a particular entity 310 basis. Detection of individual entity 310 presences or determination of respective operating states can be performed by way of the array 308 and controller 304.

The system 300 depicts one illustrative application according to the present teachings. In general, and without limitation, one or more magnetically sensitive devices are coupled in signal communication with a controller or other suitable electronic construct. The controller individually accesses (operates) each MSD by way of current drive signals and corresponding voltage sensing. Calibration data for each MSD—or a standardized calibration model—can be used to interpret the sensed voltages. Incident magnetic field intensities, operating states, entity presence or proximity, or other information can be determined according to the present teachings.

### First Illustrative Apparatus

Reference is now made to FIG. 4, which depicts a block schematic of an apparatus 400. The apparatus 400 is illustrative and non-limiting with respect to the present teachings. Other apparatuses, devices or systems can be configured and/or operated in accordance with the present teachings.

The apparatus 400 includes an array controller (controller) 402. The controller 402 can be defined by or include any suitable resources such as a microprocessor, microcontroller, digital circuitry, analog circuitry, hybrid circuitry, ASIC, etc. The controller 402 is configured to provide current drive signals by way of control lines 404. The controller 402 is also configured to sense voltages by way of sense lines 406. In this way, the controller can selectively address respective magnetically sensitive devices in accordance with the present teachings. In one embodiment, the controller 402 is essentially equivalent to the controller 304.

The apparatus 400 further includes a plurality of magnetically sensitive devices (MSDs) 408. Each MSD 408 includes a graphite containing-material (e.g., 104, etc.) and is characterized by respective current-versus-voltage response curves (e.g., 202, 206, etc.) corresponding to varying intensities of incident magnetic field strength. In one embodiment, one of more of the MSDs 408 is substantially equivalent to the magnetically sensitive device 100 as described above. Other embodiments in accordance with the present teachings can also be used.

Each of the MSD 408 is coupled to receive current drive signals from the controller 402 via an associated pair of the lines 404. In turn, each MSD 408 is coupled to provide corresponding electrical potentials to the controller 402 via an associated pair of the lines 406. The MSDs 408 are arranged and operated as an addressable array.

In one embodiment, each MSD 408 is operated as a storage cell or bit memory unit in accordance with incident magnetic flux. In another embodiment, each MSD 408 is operated as a switch or amplifier (i.e., a transistor) unit based upon incident magnetic flux intensity. Other applications corresponding to other schema can also be used.

### First Illustrative Method

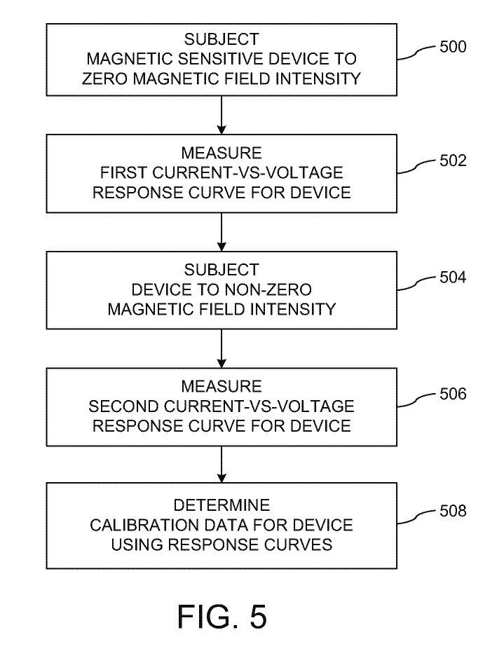

Attention is directed to FIG. 5, which depicts a flow diagram of a method according to one embodiment of the present teachings. The method of FIG. 5 includes particular operations and order of execution. However, other methods including other operations, omitting one or more of the depicted operations, and/or proceeding in other orders of execution can also be used according to the present teachings. Thus, the method of FIG. 5 is illustrative and non-limiting in nature. Reference is also made to FIGS. 1-2 in the interest of understanding the method of FIG. 5.

At 500, a magnetically sensitive device is subjected to zero magnetic field intensity. For purposes of non-limiting illustration, it is assumed that a device 100 is provided, and that no magnetic field “H” is incident to the device 100. As such, only ambient geomagnetic flux is incident to the device 100.

At 502, a first current-versus-voltage response curve is measured for the magnetically sensitive device. For purposes of the ongoing illustration, electrical current is provided to the device 100 by way of electrodes 106 and 108. This electric current is smoothly varied over a predetermined range. Contemporaneously, electric potential exhibited by the device 100 is measured by way of electrodes 112 and 114. A curve correlating the respective drive current values with the resulting voltage values, corresponding to zero magnetic flux intensity, is measured and recorded. Curve 202 is illustrative of and non-limiting with respect to such a curve.

At 504, the magnetically sensitive device is subjected to non-zero magnetic field intensity. For purposes of non-limiting illustration, it is assumed that the a magnetic field, having an intensity “H” significant for purposes of this example, is incident to the device 100. For purposes of the ongoing example, it is assumed that the device 100 is subject to a magnetic field of five-hundred Oersteds.

At 506, a second current-versus-voltage response curve is measured for the magnetically sensitive device. For purposes of the ongoing illustration, electrical current is provided to the electrodes 106 and 108 while electric potential is measured by way of electrodes 112 and 114. A curve correlating the various drive current values with the resulting voltage values, corresponding to five-hundred Oersted magnetic flux intensity, is measured and recorded. Curve 206 is illustrative of and non-limiting with respect to such a curve.

At 508, calibration data for the magnetically sensitive device is determined using the response curves. For purposes of the ongoing example, it is assumed that the curves resulting from steps 500-506 above are analyzed and a plurality of loci is selected. These loci are typically—but not necessarily—selected within or proximate to hysteresis regions (e.g., 204) of the respective curves (e.g., 202 and 206). The selected loci are used to populate a calibration data table for the device 100. These data can thereafter be used to determine (or estimate) incident magnetic field intensities, detect magnetic fields, determine one or more magnetically-determined operating states for the device 100, etc.

The foregoing method is illustrative of any number of methods contemplated by the present teachings. In general, and without limitation, a magnetically sensitive device according to the present teachings is subject to two or more known magnetic field intensities. Current-versus-voltage curves (or data) are taken for the MSD with each curve correlated to the incident magnetic field intensity to which is relates. The curves are then analyzed to identify loci particular to respective, incident magnetic field intensities.

The selected loci are typically associated with hysteresis regions exhibited by the respective curves. The selected loci are then used to construct a calibration data table for the magnetically sensitive device. The method of FIG. 5 depicts the determination of two different current-versus-voltage response curves and the compilation of calibration data there from. However, it is to be understood that any suitable number of curves, each corresponding to a respective magnetic field strength, can be measured and used in accordance with the present teachings. One or more (or all) of the steps 500-508 can be performed, at least in part, by way of computer assistance or control.

### SECOND ILLUSTRATIVE METHOD

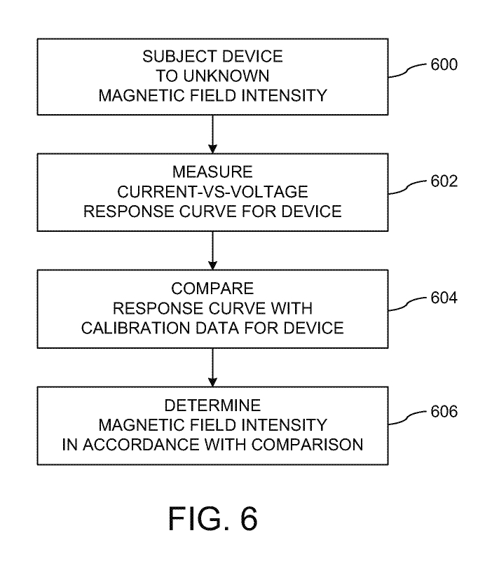

Attention is directed to FIG. 6, which depicts a flow diagram of a method according to one embodiment of the present teachings. The method of FIG. 6 includes particular operations and order of execution. However, other methods including other operations, omitting one or more of the depicted operations, and/or proceeding in other orders of execution can also be used according to the present teachings. Thus, the method of FIG. 6 is illustrative and non-limiting in nature. Reference is also made to FIGS. 1-2 in the interest of understanding the method of FIG. 6.

At 600, a magnetically sensitive device is subject to a magnetic filed of as yet unknown intensity. For purpose of non-limiting illustration, it is assumed that the MSD 100 is subjected to an unknown magnetic field “H”. Other magnetically sensitive devices according to the present teachings can also be used.

At 602, a current-versus-voltage response curve is measured for the device. For purposes of the present illustration, electrical current is driven through the device 100 by way of electrodes 106 and 108. Simultaneously, electric potential is measured across graphite containing-material 104 of the device 100 by way of electrodes 112 and 114. Measurements are taken at a plurality of distinct current values resulting in a number of current/voltage value pairs.

At 604, the response curve from 602 above is compared with calibration data for the device. For purposes of the present illustration, it is assumed that calibration data has been predetermined for the device 100 (e.g., FIG. 5, etc.). The current/voltage data pairs from step 602 are compared with the calibration data by least-squares fit or another suitable analytical technique. The closest measurement-versus-data matches are then determined.

At 606, the magnetic field intensity is determined according to the comparison. For purposes of the present illustration, it is assumed that magnetic field intensity of three-hundred Oersteds is determined (or estimated). This determination can, optionally, be correlated to a predefined operating state for the device 100, or used for another purpose, etc.

In general, and without limitation, the present teachings contemplate the determination of incident magnetic field intensities or device states. A magnetically sensitive device is subject to an unknown magnetic field strength. Calibration data for the MSD has been previously determined. A number of applied current-versus-voltage response data pairs are measured and compared to the calibration data.

The magnetic field strength, a state of the MSD, or another determination is made according to the comparison. One or more (or all) of the steps 600-606 can be performed, at least in part, by way of computer assistance or control.

In general, the foregoing description is intended to be illustrative and not restrictive. Many embodiments and applications other than the examples provided would be apparent to those of ordinary skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. An apparatus, comprising:
a substrate;
a graphite containing-material supported by the substrate;
a first pair of electrodes configured to subject the graphite containing-material to an electric current; and
a second pair of electrodes configured to sense an electric potential while the graphite containing material is subject to the electric current.

2. The apparatus according to claim 1, the substrate being defined by a semiconductor wafer.

3. The apparatus according to claim 1, the first pair of electrodes being disposed on opposite sides of the graphite containing-material so as to define a first electrode axis.

4. The apparatus according to claim 3, the second pair of electrodes being disposed on opposite sides of the graphite containing-material so as to define a second electrode axis.

5. The apparatus according to claim 4, the second electrode axis being about perpendicular to the first electrode axis.

6. The apparatus according to claim 1, the graphite containing-material being further defined by plural layers of graphene.

7. The apparatus according to claim 1, the graphite containing-material characterized by respectively different current-versus-voltage response curves when subject to correspondingly different magnetic field intensities.

8. The apparatus according to claim 7, at least one of the current-versus-voltage response curves being characterized by hysteresis.

9. The apparatus according to claim 1 further comprising electronic circuitry configured to determine an intensity of a magnetic field incident to the graphite containing material using an electric potential sensed across the second pair of electrodes.

10. The apparatus according to claim 1 further comprising electronic circuitry configured to determine a state of the apparatus using an electric potential sensed across the second pair of electrodes.

11. The apparatus according to claim 1, the graphite containing material being at least a portion of a sensor, a transistor, or a memory device.

12. A method, comprising:
subjecting a device including a graphite containing-material to a magnetic field;
sensing an electric potential across the graphite containing-material; and
determining at least a state of the device or an intensity of the magnetic field by way of the electric potential.

13. The method according to claim 12 further comprising driving an electric current through the graphite-containing material during the sensing.

14. The method according to claim 12, the determining further performed by way of calibration data for the device.

15. The method according to claim 12, the device defining at least a portion of a magnetically sensitive transistor, or a magnetically sensitive memory device.
